(19) United States
(12) Patent Application Publication
(10) Pub. No.: US 2012/0193131 A1
(43) Pub. Date: Aug. 2, 2012

(54) METAL BASE CIRCUIT BOARD AND PRODUCTION METHOD THEREOF

(75) Inventors: Kouichi Kusakawa, Kanagawa (JP); Kazuhiko Konomi, Kanagawa (JP); Satoshi Okamoto, Tsukuba-shi (JP); Toyonari Ito, Tsukuba-shi (JP)

(73) Assignees: SUMITOMO CHEMICAL COMPANY, LIMITED, Tokyo (JP); NHK SPRING CO., LTD., Yokohama-shi (JP)

(21) Appl. No.: 13/262,944

(22) PCT Filed: Apr. 7, 2010
(86) PCT No.: PCT/JP2010/056327

§ 371 Date: Oct. 5, 2011

(30) Foreign Application Priority Data
Apr. 9, 2009 (JP) 2009-094821

(51) Int. Cl. H05K 1/05; B32B 37/26; B32B 37/06

(52) U.S. Cl. 174/256; 156/308.2

(57) ABSTRACT

The metal base circuit board according to the present invention includes a metal substrate, an insulating layer provided on the metal substrate, and a conductive foil for circuit formation that is provided on the insulating layer. The metal substrate has a thermal conductivity of 60 W/mK or more and a thickness of 0.2 to 5.0 mm. The insulating layer is formed using an insulating material composition in which an inorganic filler having a thermal conductivity of 30 W/mK or more is dispersed in a non-anisotropic liquid crystal polyester solution. According to the present invention, a metal base circuit board can be provided that can be applied in an inverter and applications requiring high heat dissipation properties, and that has high thermal conductivity, as well as having high thermal stability and electrical reliability.

### TECHNICAL FIELD

The present invention relates to a metal base circuit board having excellent heat dissipation properties, and also having high electrical insulation properties and electrical reliability even at high temperatures, as well as a production method thereof.

### BACKGROUND ART

As to circuit boards for carrying semiconductors, there is a constant demand for downsizing, greater mounting density, and better performance. Such circuit boards are becoming smaller every year as a result of improvements in the downsizing technology for the semiconductor devices that are mounted on the circuit boards.

However, with the decrease in size, increase in performance, and increase in power of the semiconductor devices to be mounted on a circuit board, how to dissipate the heat produced from the semiconductor devices becomes a significant problem. Especially for circuit boards used in a high temperature environment, there is a need to improve the heat dissipation properties.

As circuit boards used in the high temperature environment, ceramic base circuit boards are mainly employed. The ceramic base circuit board has a structure in which a substrate formed of alumina or aluminum nitride is used as a support substrate, and a conductive foil for circuit formation is provided on the surface of this support substrate using metallizing technology.

Although the ceramic base circuit boards have good durability in high temperature environments, they suffer from a drawback of difficulty in manufacturing large-sized products. Further, since the ceramic substrates of ceramic base circuit boards themselves are brittle, the ceramic base circuit boards cannot be used in products used under conditions with strong vibrations, such as an electronic component in an automobile electronic product. Further, the material costs for the ceramic base circuit boards are very high, and therefore it is difficult to reduce product cost.

On the other hand, due to their excellent heat dissipation properties, metal base circuit boards are employed mainly in the power source field, such as in inverters. The metal base circuit boards have to have a structure in which an insulating layer is formed on a metal plate, and a conductive foil for circuit formation is provided on the insulating layer. Therefore, the heat generated from the semiconductor devices connected to the circuit is transmitted to the metal substrate via a resin material constituting the insulating layer, and dissipated from the metal substrate. However, because the resin constituting the insulating layer has a low thermal conductivity, the dissipation of heat from the metal base circuit board is insufficient. Thus, at present metal base circuit boards cannot be used in electronic components placed in high temperature environments. Therefore, there is an expectation of improving the heat dissipation properties of metal base circuit boards, which are available at an inexpensive product cost.

Consequently, various efforts have been made in the past to increase the thermal conductivity of the insulating layer in metal base circuit boards.

For example, in one approach to improve heat dissipation properties, an inorganic filler, which is spherical and has a wide particle size distribution, is added to a resin component at an amount of 65 to 85% by volume so that the inorganic filler is in its closest packed state in the insulating resin layer, whereby the inorganic filler with a high thermal conductivity is brought into contact with each other in the resin layer (e.g. Patent Document 1). In this approach, although the filling properties of the inorganic filler improve and thermal conductivity increases, the surface contact area of the inorganic filler particles is small, so that the achieved thermal conductivity is an insufficient 5 W/mK. Further, the resin layer becomes brittle due to a decrease in the ratio of the resin component in the insulating layer. This creates another problem of insufficient mechanical strength of the insulating layer in the obtained metal base circuit board.

Generally, the thermal conductivity of the insulating layer does not increase unless the inorganic filler particles are in contact with each other. Therefore, from the viewpoint of increasing the thermal conductivity of the insulating layer, the amount of the inorganic filler has to be increased close to the closest packed state. However, as the content of the inorganic filler increases, the content of the resin component constituting the insulating layer decreases. Consequently, the adhesion properties of the insulating layer with the metal substrate or the conductive foil remarkably deteriorate. Further, decrease in the content of the resin component also creates another problem that the insulating layer becomes more brittle. This problem is especially significant when a thermosetting resin, such as a thermosetting epoxy resin, is used as the resin component. Since such an insulating layer is very brittle, cutting process of the metal base circuit board having this insulating layer tends to generate debris of the insulating layer. The debris thus generated causes a number of problems during processing. For example, the debris acts as particles which cause deterioration of the substrate. The particles also remain on the substrate during pressing, and cause damages of dents on the substrate.

As another prior art, there is disclosed a metal base circuit board that uses boron nitride, diamond, or beryllium oxide, which have a high thermal conductivity, as an inorganic filler and an epoxy resin as a resin component (Patent Document 2).

However, as stated above, even if the layer is filled with the inorganic filler having a high thermal conductivity up to its closed packed state, the increase in the contact surface area of the inorganic filler particles is tiny, so that most of the heat passes through the resin layer. Since the resin has a low thermal conductivity, the heat is blocked by the resin layer. Even in the structure disclosed in Patent Document 2, the thermal conductivity of the overall insulating layer is at most 12.4 W/mK, since the resin component is of an amorphous epoxy resin having a low thermal conductivity, and transmission of heat is interrupted by this resin layer.

As another prior art, there is disclosed a structure in which either bismaleimide triazine (BT resin) or polyphenylene oxide is used as the resin component and alumina or aluminum nitride is used as the inorganic filler (Patent Document 3).

However, even if a rigid resin like BT resin is employed, the resin is also amorphous and therefore has low thermal conductivity. Therefore, as stated above, the resin component blocks the heat transmission path. Consequently, the thermal conductivity of the obtained insulating layer is at most about 7.5 W/mK.

As still another prior art, there is disclosed an electrical component substrate having an insulating layer with a structure in which a melt-moldable thermotropic liquid crystal polyester that exhibits anisotropicity is used as the resin component, and a filler having a thermal conductivity of 10 W/mK or more at 300° K is used as the filler (Patent Document 4).

In this art, addition of the inorganic filler to the melt resin causes extremely high melt viscosity of the resin. Therefore, the content of the inorganic filler can not be elevated. Consequently, the thermal conductivity of the insulating layer cannot be increased.

Further, because of the high viscosity of the resin during extrusion, a thin film of about 100 to 200 μm cannot be sheeted. Since preferable thickness of the insulation layers of metal base boards is 50 to 200 μm, the material described in Patent Document 4 is completely unavailable as an insulating layer of a metal base circuit board. This can be confirmed from the fact that, as disclosed in Example 1 of Patent Document 4, the content of alumina relative to the liquid crystal polyester is as low as 35% by volume, the extrusion thickness is as thick as 0.4 mm, and the thermal conductivity is as low as 1.5 W/mK.

In addition, when a liquid crystal polyester that exhibits anisotropicity is sheeted by extrusion, the polymer orients in the extrusion direction, which causes high thermal conductivity in the length direction and low thermal conductivity in the thickness direction. In a metal base circuit board, the heat generated at the circuit flows from the circuit layer on the insulating layer toward the metal substrate in a vertical (thickness direction) manner across the insulating layer. Therefore, it is preferred that the thermal conductivity of the insulating layer is high in the thickness direction. However, in the structure disclosed in Patent Document 4, the thermal conductivity of the insulating layer is low in the thickness direction, by which the heat dissipation properties of the metal base circuit board inevitably becomes insufficient.

### PRIOR ART DOCUMENTS

### Patent documents

Patent Document 1: Japanese Patent Application Laid-Open No. Hei 5-167212

Patent Document 2: Japanese Patent Application Laid-Open No. Hei 7-320538

Patent Document 3: Japanese Patent Application Laid-Open No. Hei 6-188530

Patent Document 4: Japanese Patent Publication No. Hei 6-082893

### SUMMARY OF THE INVENTION

### Problem to be solved by the Invention

The present invention was created in view of the above-described circumstances. It is an object of the present invention to provide a metal base circuit board which can be applied in an inverter and applications requiring high heat dissipation properties, and which has high thermal conductivity as well as high thermal stability and electrical reliability.

Although ceramic base circuit boards have an advantage of possessing excellent heat resistance, they suffer from the drawbacks that large boards are difficult to form and that they are weak against shocks. Therefore, it is also an object of the present invention to provide a metal base circuit board which does not suffer from such drawbacks, which combines heat resistance, insulation properties and reliability, and which can be used in the same application fields as a ceramic base circuit board. The metal base circuit board according to the present invention may be used as a board for automobile applications, such as an electric power steering control unit, an LED head-up display, an automatic transmission, an ABS module, an engine control unit, and an LED meter panel. As other applications, the metal base circuit board may also be used as a board in LED lighting equipment or an LED display backlight, and as a power board in, e.g., an elevator and a train.

### Means for solving the Problem

In order to solve the above-described problems, a metal base circuit board according to the present invention includes a metal substrate, an insulating layer provided on the metal substrate, and a conductive foil for circuit formation that is provided on the insulating layer, wherein: the metal substrate has a thermal conductivity of 60 W/mK or more and a thickness of 0.2 to 5.0 mm, and the insulating layer is formed using an insulating material composition in which an inorganic filler having a thermal conductivity of 30 W/mK or more is dispersed in a non-anisotropic liquid crystal polyester solution.

In the aforementioned configuration, an insulating material constituting the insulating layer preferably has a thermal conductivity of 6 to 30 W/mK.

Further, a method for producing a metal base circuit board according to the present invention is a method for producing the metal base circuit board according to the above described present invention and includes: an applied insulating-material-composition layer formation step of applying an insulating material composition containing a non-anisotropic liquid crystal polyester solution and an inorganic filler having a thermal conductivity of 30 W/mK or more on a surface of a metal substrate having a thermal conductivity of 60 W/mK or more and a thickness of 0.2 to 5.0 mm to form an applied insulating-material-composition layer; an insulating material layer formation step of drying the applied insulating-material-composition layer to form an insulating material layer; an insulating layer formation step of heat-treating the insulating material layer for increasing its molecular weight to obtain an insulating layer; a lamination step of bringing the conductive foil into contact with an exposed surface of the insulating layer formed on the surface of the metal substrate to form a multi-layer structure in which the insulating layer is provided between the metal substrate and the conductive foil; and after the lamination step, a thermal adhesion step of heating the insulating layer to adhere the insulating layer with the metal substrate and the conductive foil.

Another configuration of the method for producing the metal base circuit board according to the above described present invention includes: an applied insulating-material-composition layer formation step of applying an insulating material composition containing a non-anisotropic liquid crystal polyester solution and an inorganic filler having a thermal conductivity of 30 W/mK or more on a surface of a conductive foil to form an applied insulating-material-composition layer; an insulating material layer formation step of drying the applied insulating-material-composition layer to form an insulating material layer; an insulating layer formation step of heat-treating the insulating material layer for increasing its molecular weight to obtain an insulating layer; a lamination step of bringing an exposed surface of the insulating layer formed on the surface of the conductive foil into contact with a surface of the metal substrate to form a multi-layer structure in which the insulating layer is provided between the metal substrate and the conductive foil; and after the lamination step, a thermal adhesion step of heating the insulating layer to adhere the insulating layer with the metal substrate and the conductive foil.

### Effect of the Invention

The metal base circuit board according to the present invention uses a liquid crystal polymer having a high thermal conductivity as a matrix (host material) for the insulating material constituting the insulating layer. Consequently, the thermal conductivity of the insulating layer that transmits heat from the conductive foil to the metal substrate can be greatly improved, and the high heat dissipation properties possessed by the metal substrate can be fully utilized.

Further, in the method for producing the metal base circuit board according to the present invention, a liquid crystal polyester solution is used. Because this liquid crystal polymer solution can be easily blended with a large amount of inorganic filler, a desired amount of inorganic filler can be dispersed uniformly in the resin component. Consequently, a product having a high thermal conductivity can be obtained.

In addition, according to the present invention, since the resin component constituting the host material of the insulating layer itself has high the thermal conductivity, the thermal conductivity of the insulating layer can be maintained at a high level even if the amount of the inorganic filler is reduced. Consequently, the thermal conductivity of the insulating layer can be improved while simultaneously ensuring the insulation properties and mechanical strength of the insulating layer.

Therefore, a product obtained based on the present invention has high heat dissipation properties as well as excellent mechanical strength, so that the product can be subject to cutting and pressing. Further, the product can be obtained at a low cost, and can be applied in a wide range of fields including fields in which ceramic base circuit boards have mainly been used.

### EMBODIMENTS FOR CARRYING OUT THE INVENTION

As described above, the elements constituting the metal base circuit board according to the present invention can broadly be broken down into three types that are a metal substrate, an insulating layer provided on the metal substrate, and a conductive foil for circuit formation that is provided on the insulating layer. These three constituent elements will now be successively described in detail below.

### Metal Substrate

A metal plate having a thermal conductivity of 60 W/mK or more is used as the metal substrate used in the present invention. Examples of metal materials constituting the metal substrate may include aluminum, aluminum alloys, iron, copper, stainless steel, alloys of these metals, and modified aluminum forming a composite structure with carbon that has a high thermal conductivity. The thickness of the metal substrate is preferably 0.2 to 5.0 mm.

### Conductive Foil

The conductive foil used in the metal base circuit board of the present invention is preferably a copper foil or an aluminum foil. The thickness of the conductive foil is preferably 10 to 400 μm.

### Insulating Layer

The insulating layer is obtained by applying a below-described specific insulating material composition onto a face (adhering face) of one of the conductive foil and metal substrate, drying the applied layer, and then heat treating the insulating material layer that was obtained by the drying to increase the molecular weight of the resin component constituting the insulating material layer.

The other of the conductive foil and metal substrate on which the applied layer is not formed is provided after the insulating layer is formed by the above-described heat treatment.

Further, the insulating layer used in the present invention may be a film-like object that has been prepared separately from the conductive foil and metal substrate. In this case, the film-like insulating layer is arranged between the conductive foil and the metal substrate, and the resultant multi-layer body is heated to realize adhesion to the conductive foil and the metal substrate. It is preferred that this heat treatment be carried out at a temperature of 250 to 350° C. for 1 to 10 hours.

Further, during the thermal adhesion, it is preferred to apply pressure in the thickness direction of the multi-layer body.

### Insulating Material Composition

The insulating material composition used to form the insulating layer contains a non-anisotropic liquid crystal polyester solution and an inorganic filler having a thermal conductivity of 30 W/mK or more. The non-anisotropic polyester solution is a polymer solution formed by dissolving a liquid crystal polyester in a solvent and optionally adding other additives.

### Liquid Crystal Polyester

The liquid crystal polyester used in the present invention exhibits optical anisotropy when melted and forms an anisotropic melt state at a temperature of 450° C. or less.

The liquid crystal polyester forming an anisotropic melt state has a structural unit represented by the following general formula (1), a structural unit represented by the following general formula (2), and a structural unit represented by the following general formula (3).

—O—Ar¹—CO— (1)

—CO—Ar²—CO— (2)

-X-Ar³-Y- (3)

(wherein Ar1 in the formula (1) represents phenylene or naphthylene, Ar2 in the formula (2) represents phenylene, naphthylene, or a group represented by the following formula (4), Ar3 in the formula (3) represents phenylene or a group represented by the following formula (4), X and Y represent O or NH, and X and Y may be the same or different; further, the hydrogen atoms bonded to the aromatic ring of Ar¹, Ar², and Ar³ may be substituted with a halogen atom, an alkyl group, or an aryl group.)

—Ar¹¹-Z-Ar¹²— (4)

(wherein Ar¹¹ and Ar¹² in the formula (4) each independently represent phenylene or naphthylene, and Z represents O, CO, or SO₂.)

The ratio of the respective structural units represented by the general formulae (1) to (3) is preferably, based on the total of all the structural units, 30.0 to 45.0 mol % for the structural unit represented by the general formula (1), 27.5 to 35.0 mol % for the structural unit represented by the general formula (2), and 27.5 to 35.0 mol % for the structural unit represented by the general formula (3).

The liquid crystal polyester used in the present invention is preferably a polymer that includes 27.5 to 35.0 mol % of at least one kind of a structural unit (a) selected from the group consisting of structural units derived from an aromatic diamine and structural units derived from an aromatic amine having a hydroxyl group based on all the structural units. In particular, if the liquid crystal polyester has the structural unit (a) as the structural unit represented by the general formula (3), the above-described effect, specifically, of “exhibiting optical anisotropy when melted and forming an anisotropic melt state at a temperature of 450° C. or less” tends to be obtained better.

The structural unit represented by the general formula (1) is derived from an aromatic hydroxy-carboxylic acid. The structural unit represented by the general formula (2) is derived from an aromatic dicarboxylic acid. The structural unit represented by the general formula (3) is derived from an aromatic diamine or an aromatic amine having a phenolic hydroxyl group. The liquid crystal polyester used in the present invention is obtained by using the compounds deriving these structural units (1) to (3), respectively, as monomers and polymerizing these monomers.

From the viewpoint of facilitating the polymerization reaction for obtaining the aromatic liquid crystal polyester used in the present invention, instead of the above-described monomers, ester-forming derivatives or amide-forming derivatives thereof may be used.

Examples of ester-forming derivatives or amide-forming derivatives of the above-described carboxylic acids may include highly reactive derivatives such as acid chlorides and acid anhydrides, wherein the carboxyl group promotes a reaction for producing a polyester or a polyamide, and derivatives that are in a form of an ester with an alcohol, ethylene glycol and the like, wherein the carboxyl group produces a polyester or a polyamide by a transesterification reaction or a transamidation reaction.

Further, examples of ester-forming derivatives or amide-forming derivatives of the above-described phenolic hydroxyl group may include derivatives in which the phenolic hydroxyl group are in a form of an ester with a carboxylic acid so that a polyester or a polyamide is produced by a transesterification reaction.

In addition, examples of amide-forming derivatives of the above-described amino group may include derivatives in which the amino group is in a form of an ester with a carboxylic acid so that a polyamide is produced by a transamidation reaction.

Specific examples of the structural units represented by the above-described general formulae (1) to (3) may include, but are not limited to, the following.

Examples of the structural unit represented by the general formula (1) may include a structural unit derived from an aromatic hydroxy-carboxylic acid selected from p-hydroxy benzoic acid, 6-hydroxy-2-naphthoic acid, and 4-hydroxy-4′-biphenyl carboxylic acid. Of these, two kinds or more structural units may be included. It is especially preferred to use an aromatic liquid crystal polyester having a structural unit derived from p-hydroxy benzoic acid or from 2-hydroxy-6-naphthoic acid.

The amount of the structural unit represented by the general formula (1) is, based on the total of all the structural units, in the range of 30.0 to 45.0 mol %, and more preferably in the range of 35.0 to 40.0 mol %.

If the amount of the structural unit represented by the general formula (1) exceeds 45.0 mol %, the solubility in the below-described aprotic solvent tends to deteriorate, while if the amount is less than 30.0 mol %, the polyester tends to not exhibit liquid crystallinity. Accordingly, these ranges are not preferred.

Examples of the structural unit represented by the general formula (2) may include a structural unit derived from an aromatic dicarboxylic acid selected from terephthalic acid, isophthalic acid, and 2,6-naphthalenedicarboxylic acid. Of these, two kinds or more structural units may be included. From the viewpoint of solubility in the below-described aprotic solvent, it is preferred to use a liquid crystal polyester having a structural unit derived from isophthalic acid.

The amount of the structural unit represented by the general formula (2) is, based on the total of all the structural units, in the range of 27.5 to 35.0 mol %, and more preferably in the range of 30.0 to 32.5 mol %.

If the amount of the structural unit represented by the general formula (2) exceeds 35.0 mol %, liquid crystallinity tends to deteriorate, while if the blended amount is less than 27.5 mol %, the solubility in the aprotic solvent tends to deteriorate. Accordingly, these ranges are not preferred.

Examples of the structural unit represented by the general formula (3) may include a structural unit derived from an aromatic amine having a phenolic hydroxyl group such as 3-aminophenol or 4-aminophenol, and a structural unit derived from an aromatic diamine such as 1,4-phenylenediamine or 1,3-phenylenediamine. Of these, two kinds or more structural units may be included. From the viewpoint of the polymerization reactivity of the liquid crystal polyester manufacture, it is preferred to use a liquid crystal polyester having a structural unit derived from 4-aminophenol.

The amount of the structural unit represented by the general formula (3) is, based on the total of all the structural units, in the range of 27.5 to 35.0 mol %, and more preferably in the range of 30.0 to 32.5 mol %.

If the amount of the structural unit represented by the general formula (3) exceeds 35.0 mol %, liquid crystallinity tends to deteriorate, while if the amount is less than 27.5 mol %, the solubility in the aprotic solvent tends to deteriorate. Accordingly, these ranges are not preferred.

Although it is preferred that the amount of the structural unit represented by the general formula (3) and the amount of the structural unit represented by the general formula (2) be essentially the same, the amount of the structural unit represented by the general formula (3) may be set −10 mol % to +10 mol % with respect to the amount of the structural unit represented by the general formula (2) to control the degree of polymerization of the aromatic liquid crystal polyester.

The method for producing the above-described aromatic liquid crystal polyester is not particularly limited. As an example, the phenolic hydroxyl group or amino group of an aromatic hydroxy-carboxylic acid corresponding to the structural unit represented by the general formula (1) and the aromatic amine or aromatic diamine having a hydroxyl group corresponding to the structural unit represented by the general formula (3) may be acylated with an excess amount of a fatty acid anhydride to obtain an acylated product (ester-forming derivative or amide-forming derivative), and then the obtained acylated product may be subjected to transesterification (polycondensation) with the aromatic dicarboxylic acid corresponding to the structural unit represented by the general formula (2), to achieve melt polymerization.

As the acylated product, a fatty acid ester acylated in advance may be used (refer to Japanese Patent Application Laid-Open Nos. 2002-220444 and 2002-146003).

In the acylation reaction, it is preferred to add the fatty acid anhydride in the amount of 1.0 to 1.2 times by equivalent, and more preferably 1.05 to 1.1 times by equivalent, with respect to the total amount of the phenolic hydroxy group and the amino group.

If the amount of the fatty acid anhydride is less than 1.0 time by equivalent, the acylated product and the raw material monomers etc. sublime during transesterification (polycondensation), so that the reaction system tends to become blocked. Further, if the amount of the fatty acid anhydride exceeds 1.2 times by equivalent, coloration of the obtained aromatic liquid crystal polyester tends to become significant.

It is preferred to carry out the acylation reaction at 130 to 180° C. for 5 minutes to 10 hours, and more preferably at 140 to 160° C. for 10 minutes to 3 hours.

Examples of the fatty acid anhydride used in the acylation reaction may include, but are not particularly limited to, acetic acid anhydride, propionic acid anhydride, butyric acid anhydride, isobutyric acid anhydride, valeric acid anhydride, pivalic acid anhydride, 2-ethylhexanoic acid anhydride, monochloroacetic acid anhydride, dichioroacetic acid anhydride, trichioroacetic acid anhydride, monobromoacetic acid anhydride, dibromoacetic acid anhydride, tribromoacetic acid anhydride, monofluoro acetic acid anhydride, difluoroacetic acid anhydride, trifluoroacetic acid anhydride, glutaric acid anhydride, maleic acid anhydride, succinic acid anhydride, and β-bromopropionic acid anhydride. Mixtures of two kinds or more of these may also be used.

Among these, from the viewpoint of cost and handling ability, acetic acid anhydride, propionic acid anhydride, butyric acid anhydride, and isobutyric acid anhydride are preferred, and more preferred is acetic acid anhydride.

In the transesterification or transamidation, it is preferred that the acyl groups of the acylated product exist in the amount of 0.8 to 1.2 times by equivalent with respect to the carboxyl groups.

It is preferred to carry out the transesterification or transamidation at 130 to 400° C. while increasing the temperature at a rate of 0.1 to 50° C. per minute, and more preferably at 150 to 350° C. while increasing the temperature at a rate of 0.3 to 5° C. per minute.

During the transesterification or transamidation between the fatty acid ester obtained by acylation and the carboxylic acid or amine, it is preferred to remove fatty acids formed as byproducts and unreacted fatty acid anhydride from the system by volatilization or the like to shift the equilibrium.

The acylation reaction, transesterification and transamidation may be carried out in the presence of a catalyst. As this catalyst, a catalyst that is commonly employed as a polyester polymerization catalyst may be used. Examples thereof may include metal salt catalysts such as magnesium acetate, stannous acetate, tetrabutyl titanate, lead acetate, sodium acetate, potassium acetate, and antimony trioxide, and organic compound catalysts such as N,N-dimethylaminopyridine and N-methylimidazole.

Among these catalysts, it is preferred to use a heterocyclic compound that includes two or more nitrogen atoms, such as N,N-dimethylaminopyridine and N-methylimidazole (refer to Japanese Patent Application Laid-Open No. 2002-146003).

The catalyst is usually added when adding the monomers. It is not necessary to remove the catalyst after acylation. In the case of not removing the catalyst, the mixture as it is may be subjected to the transesterification reaction.

Although the polymerization by transesterification or transamidation is usually carried out by melt polymerization, melt polymerization and solid state polymerization can be combined. The solid state polymerization may be carried out based on a known solid state polymerization method after extracting a polymer from the melt polymerization step and then crushing the obtained polymer into a powder or flakes. A specific example of such a method may be a heat treatment in an inert atmosphere such as nitrogen, at 20 to 350° C., for 1 to 30 hours in a solid phase state. The solid state polymerization may be carried out while stirring or in a still state without stirring.

By providing a suitable stirring mechanism, the same polymerization vessel may be used for the melt polymerization vessel and the solid state polymerization vessel.

After the solid state polymerization, the obtained aromatic liquid crystal polyester may be pelletized to be in a certain shape by a known method.

Production of the aromatic liquid crystal polyester may be carried out using, for example, a batch apparatus or a continuous apparatus.

It is preferred that a flow start temperature of the aromatic liquid crystal polyester evaluated by the following method is 260° C. or more, for achieving more dense adhesion between the obtained aromatic liquid crystal polyester and the base material that can serve as the conductive layer, such as a metal foil, as well as between the aromatic liquid crystal polyester and the metal substrate.

Further, it is more preferred if the flow start temperature is 250° C. or more and 300° C. or less. If the flow start temperature is 250° C. or more, as described above, the adhesion of the aromatic liquid crystal polyester with each of the conductive foil and the metal substrate tends to be better. If the flow start temperature is 300° C. or less, better solubility in the solvent tends to be seen. From this viewpoint, the flow start temperature is more preferably in the range of 260° C. or more and 290° C. or less.

The term “flow start temperature” refers to the temperature at which, during evaluation of melt viscosity by a flow tester, the melt viscosity of the aromatic polyester is 4800 Pa·s or less under a pressure of 9.8 MPa.

According to the book “Synthesis, Shaping, and Applications of Liquid Crystal Polymers” published in 1987 (edited by Naoyuki Koide, pp. 95 to 105, CMC, published on Jun. 5, 1987), ever since liquid crystal polyester resins were developed in the 1970s, the flow temperature (same definition as “flow start temperature” in the present invention) has been used as an index for the molecular weight of liquid crystal polyester resins.

The flow start temperature of an aromatic liquid crystal polyester can be easily controlled by, for example, extracting a polymer from the melt polymerization step, crushing the polymer into a powder or flakes, and then adjusting the flow start temperature by a known solid state polymerization method.

More specifically, the solid state polymerization may be performed by, after the melt polymerization step, a heat treatment in an inert atmosphere such as nitrogen at a temperature exceeding 210° C., more preferably at a temperature of 220° C. to 350° C., for 1 to 10 hours in a solid phase state. The solid state polymerization may be carried out while stirring or in a still state without stirring. For example, solid state polymerization may be carried out in a still state without stirring in an inert atmosphere such as nitrogen at a temperature of 225° C. for 3 hours.

### Solvent for Non-Anisotropic Liquid Crystal Polyester Solution

As the solvent for dissolving the liquid crystal polyester to obtain the non-anisotropic liquid crystal polyester solution used in the present invention, it is preferred to use an aprotic solvent that does not contain a halogen atom.

Examples of the aprotic solvent that does not contain a halogen atom may include ether solvents such as diethylether, tetrahydrofuran, and 1,4-dioxane; ketone solvents such as acetone and cyclohexanone; ester solvents such as ethyl acetate; lactone solvents such as γ-butyrolactone; carbonate solvents such as ethylene carbonate and propylene carbonate; amine solvents such as triethylamine and pyridine; nitrile solvents such as acetonitrile and succinonitrile; amide solvents such as N,N-dimethylformamide, N,N-dimethylacetoamide, tetramethylurea, and N-methylpyrrolidone; nitro solvents such as nitromethane and nitrobenzene; sulfide solvents such as dimethylsulfoxide and sulfolane; and phosphoric acid solvents such as hexamethylphosphoric amide and tri-n-butyl phosphate.

Among these, from the viewpoint of the solubility of the above-described aromatic liquid crystal polyester, it is preferred to use a solvent which has a dipole moment of 3 or more and 5 or less. Specifically, it is preferred to use an amide solvent such as N,N-dimethylformamide, N,N-dimethylacetoamide, tetramethylurea, and N-methylpyrrolidone or a lactone solvent such as γ-butyrolactone, and more preferably N,N-dimethylformamide, N,N-dimethylacetoamide, or N-methylpyrrolidone (NMP). In addition, the solvent is preferably a highly volatile solvent having a boiling point of 180° C. or less at 1 atmospheric pressure, because thereby, after forming a layer of the insulating material composition including the aromatic liquid crystal polyester solution, removal of the solvent from the applied layer may be facilitated. From this viewpoint, N,N-dimethylformamide (DMF) and N,N-dimethylacetoamide (DMAc) are especially preferred.

The non-anisotropic liquid crystal polyester solution used in the present invention contains 10 to 50 parts by weight, and preferably 20 to 40 parts by weight of the aromatic liquid crystal polyester based on 100 parts by weight of the above-described aprotic solvent.

If the content of the aromatic liquid crystal polyester is less than 10 parts by weight, the solvent fraction is large, so that the appearance of the applied layer tends to be poor when the solvent is removed by drying. If the content of the aromatic liquid crystal polyester is more than 50 parts by weight, the viscosity of the aromatic liquid crystal polyester solution tends to increase, so that handling ability deteriorates. The aromatic liquid crystal polyester content in the solution composition can be appropriately optimized in the aforementioned range based on the balance with the solution viscosity. A more preferred content is 20 to 40 parts by weight of aromatic liquid crystal polyester based on 100 parts by weight of the above-described aprotic solvent.

The liquid crystal polyester used as a host material for the insulating layer in the metal base circuit board according to the present invention has a comparatively small pre-thermal curing molecular weight. Therefore, this liquid crystal polyester can comparatively easily form a solution, and thus easily form an applied layer. Further, after the applied layer is formed, the molecular weight of the resin constituting the applied layer can be increased by drying and subsequent heat treatment. Consequently, the obtained insulating layer has excellent mechanical strength.

Since the liquid crystal polyester is thermoplastic, the liquid crystal polyester does not change over time during storage unlike thermosetting resins such as epoxy resin. Consequently, the liquid crystal polyester can be stably used as an industrial product. Further, since the liquid crystal polyester is thermoplastic, orientation can be fully developed, which allows a long path length of phonon conduction to be achieved by a heating process which sufficiently increases the molecular weight. Therefore, the thermal conductivity can be greatly improved. In addition, this also allows a tough insulating layer with high adhesion to be formed. Therefore, by forming the insulating layer using this liquid crystal polyester as a host material, a high-quality, high-electrically-reliable product can be obtained while satisfying the workability of the metal base circuit board.

### Inorganic Filler

The inorganic filler for use in the present invention has to be chosen from those having a thermal conductivity of 30 W/mK or more and excellent insulation properties. Particles of alumina, magnesium oxide, beryllium oxide, aluminum hydroxide, zinc oxide, aluminum nitride, boron nitride and the like are preferred.

It is preferred that the particles have a spherical shape, in consideration of the fact that the viscosity of the insulating material composition that is adjusted by blending with the above-described non-anisotropic liquid crystal polyester solution does not increase and the fact that it is easy to densely pack the inorganic filler particles in the liquid crystal polyester resin. If the particles are not spherically shaped, it is preferred to form the inorganic filler into a fine powder and then shape the fine powder into a roughly spherical shape by a powder spray method.

In order to improve the adhesion properties and dispersion properties with the resin, it is preferred to treat the surface of the inorganic filler particles with a surface treatment agent. Preferable examples of the surface treatment agent may include a silane coupling agent, a titanium coupling agent, an aluminum or zirconium coupling agent, a long-chain fatty acid, an isocyanate compound, and a polar polymer or a reactive polymer having an epoxy group, a methoxysilane group, an amino group and a hydroxyl group.

### Production Process of Metal Base Circuit Board

The above-described resin component (liquid crystal polyester), the above-described inorganic filler, and optionally other additives are dissolved or dispersed in the solvent to form a varnish (insulating material composition). This varnish is applied on the metal foil or metal substrate and the other base materials. The solvent is then removed by heating to form an insulating layer.

It is important that the inorganic filler is evenly dispersed. In order to achieve the dispersion, for example, the resin component, the coupling agent such as a silane coupling agent or titanium coupling agent, and optionally an ion adsorbent are added into the solvent, and dissolved or dispersed therein. Then, an appropriate amount of inorganic filler is added and dispersed in the resin solution while pulverizing the filler with a ball mill, a three-roll roller, a centrifugal stirrer, a bead mill or the like.

The applying method of the obtained insulating material composition may be roll coating, bar coating, screen printing and the like, and may be a continuous method or a single plate method.

The metal conductive foil with an insulating layer can be produced by using a copper foil as a base material in continuous applying method.

In the single plate method, a plate made of an iron, copper, or aluminum may be used.

Aforementioned are the fundamental features of the method for producing the metal base circuit board according to the present invention, focusing on how the insulating layer is formed. When considering the overall production method including the lamination order of the main constituent elements, which are the conductive foil, the insulating layer and the metal substrate, the following three processes can be thought of.

### First Process

The first process includes: an applied insulating-material-composition layer formation step of applying an insulating material composition containing a non-anisotropic liquid crystal polyester solution and an inorganic filler having a thermal conductivity of 30 W/mK or more on a surface of a metal substrate having a thermal conductivity of 60 W/mK or more and a thickness of 0.2 to 5.0 mm to form an applied insulating-material-composition layer; an insulating material layer formation step of drying the applied insulating-material-composition layer to form an insulating material layer; an insulating layer formation step of heat-treating the insulating material layer to for increasing its molecular weight to obtain an insulating layer; a lamination step of bringing the conductive foil into contact with an exposed surface of the insulating layer formed on the surface of the metal substrate to form a multi-layer structure in which the insulating layer is provided between the metal substrate and the conductive foil; and after the lamination step, a thermal adhesion step of heating the insulating layer to adhere the insulating layer with the metal substrate and the conductive foil.

### Second Process

The second process includes: an applied insulating-material-composition layer formation step of applying an insulating material composition containing a non-anisotropic liquid crystal polyester solution and an inorganic filler having a thermal conductivity of 30 W/mK or more on a surface of a conductive foil to form an applied insulating-material-composition layer; an insulating material layer formation step of drying the applied insulating-material-composition layer to form an insulating material layer; an insulating layer formation step of heat-treating the insulating material layer for increasing its molecular weight to obtain an insulating layer; a lamination step of bringing an exposed surface of the insulating layer formed on the surface of the conductive foil into contact with a surface of the metal substrate to form a multi-layer structure in which the insulating layer is provided between the metal substrate and the conductive foil; and after the lamination step, a thermal adhesion step of heating the insulating layer to adhere the insulating layer with the metal substrate and the conductive foil.

### Third Process

The third process includes: an insulating layer formation step of applying an insulating material composition containing a non-anisotropic liquid crystal polyester solution and an inorganic filler having a thermal conductivity of 30 W/mK or more on a surface of a separate support base material, drying the obtained applied insulating-material-composition layer, and heat-treating the dried applied insulating-material-composition layer for increasing its molecular weight to obtain a film as an insulating layer; a lamination step of peeling the film of the insulating layer off the support base material and disposing the insulating layer between the conductive foil and the metal substrate to form a multi-layer structure in which the insulating layer is provided between the metal substrate and the conductive foil; and a thermal adhesion step of heating the insulating layer to adhere the insulating layer with the metal substrate and the conductive foil.

In each of the above processes, the insulating layer is adhered to the conductive foil and the metal substrate by heating the insulating layer. This is because the liquid crystal polyester constituting the insulating material composition is a thermoplastic resin. Therefore, the adhesion between the respective layers in the multi-layer structure can be reliably achieved by a simple method of heat adhesion.

The metal base circuit board according to the present invention can be produced using any of the three processes described above.

As described above, according to the present invention, a liquid crystal polyester having a high thermal conductivity is used as a resin component serving as a host material for the insulating layer, and a thermally conductive inorganic filler is blended in the liquid crystal polyester, whereby the thermal conductivity of the insulating layer can be substantially improved.

Further, it is no longer necessary to excessively increase the amount of inorganic filler as a result of remarkable improvement in the thermal conductivity of the resin component serving as a host material for the insulating layer. Consequently, the amount of the resin component can be increased, which allows the insulating properties and mechanical strength of the insulating layer to be improved.

In addition, since the liquid crystal polyester has excellent thermal adhesive properties to metal, it is not necessary to perform a step solely dedicated to adhesion with adhesion means such as an adhesive, whereby production may be simplified and economical.

Thus, the metal base circuit board according to the present invention has high heat dissipation properties and therefore has high electrical reliability. In addition, the metal base circuit board according to the present invention has an insulating layer having high insulation properties and mechanical strength. Therefore, the metal base circuit board according to the present invention can be applied as an inexpensive substitute product for ceramic substrates which are used in, e.g., an inverter.

### EXAMPLES

Examples of the present invention will now be described. The examples illustrated below are preferred examples for describing the present invention, and do not limit the present invention.

### (1) Production of Liquid Crystal Polyester

A reaction vessel equipped with a stirring apparatus, a torque meter, a nitrogen gas inlet tube, a thermometer, and a reflux condenser was charged with 1976 g (10.5 moles) of 6-hydroxy-2-naphthoic acid, 1474 g (9.75 moles) of 4-hydroxyacetanilide, 1620 g (9.75 moles) of isophthalic acid, and 2374 g (23.25 moles) of acetic acid anhydride. The reaction vessel were thoroughly purged with nitrogen. Then, the temperature was increased to 150° C. over 15 minutes under a nitrogen gas flow, and the mixture was refluxed for three hours while maintaining that temperature.

Then, while removing by distillation byproduct acetic acid and unreacted acetic acid anhydride, the temperature was increased to 300° C. over 170 minutes. The reaction was deemed to have finished when an increase in torque was recognized. The contents were removed, and then cooled to room temperature. The contents were pulverized with a pulverizer to obtain a powder of a liquid crystal polyester having a comparatively low molecular weight. The flow start temperature of the obtained powder was measured using the Flow Tester CFT-500 from Shimadzu Corporation, and found out to be 235° C. This liquid crystal polyester powder was heated in a nitrogen atmosphere at 223° C. for 3 hours, to accomplish solid state polymerization. The flow start temperature of the liquid crystal polyester after solid state polymerization was 270° C.

### (2) Preparation of Liquid Crystal Polyester Solution A

2200 g of the liquid crystal polyester obtained in the above-described (1) was added into 7800 g of N,N-dimethylacetoamide (DMAc), and then the resultant mixture was heated at 100° C. for 2 hours to obtain a liquid crystal polyester solution A. The solution viscosity of this solution composition was 320 cP. This solution viscosity is a value measured at a measurement temperature of 23° C. using a B-type viscometer (“Model TVL-20”, rotor No. 21 (rotation speed: 5 rpm), manufactured by Toki Sangyo Co., Ltd.).

### Example 1

65% by volume filling ratio of spherical alumina (Trade name: “AS-40”, average particle size 11 μm, manufactured by Showa Denko K. K.) was blended in 100 parts of the liquid crystal polyester solution A which had a solid content of 22% to produce an insulating material solution. The insulating material solution was stirred by a centrifugal stirring and defoaming machine for 5 minutes, and then applied to a 70 μm-thick copper foil to form a layer having a thickness of about 300 μm. This was dried for 20 minutes at 100° C., and then heat-treated at 320° C. for 3 hours. This copper foil with the insulating material composition coated thereon was laminated on a metal substrate that is a 2.0 mm-thick aluminum alloy having a thermal conductivity of 140 W/mK. The laminated product was thermally adhered by heat-treating at a pressure of 50 kg/cm² and a temperature of 340° C. for 20 minutes.

Using the obtained metal base circuit board as a sample, thermal conductivity, solder resistance, withstanding voltage, and T-peel strength were evaluated under the following measurement conditions.

### Thermal Conductivity

A transistor C2233 was attached with solder to a substrate having a substrate size of 30×40 mm and a land size of 14×10 mm. A water-cooling apparatus was set on the back side of the substrate using thermally conductive silicone grease. The temperature on the surface of the transistor that was generating heat upon supplying 30 W power and the temperature of the cooling apparatus were measured. The thermal resistance value was calculated based on the equation: thermal resistance value={(transistor surface temperature)−(cooling apparatus surface temperature)}/load power. Based on the thermal resistance value, the thermal conductivity was calculated using a converting formula.

### Solder Resistance

A substrate having a substrate size of 50×50 mm and a land size of 25×50 mm (copper foil on the right half was left unremoved) was placed on a 300° C. solder bath for 4 minutes. Evaluation was carried out by visually observing whether there was any swelling or peeling.

### Withstanding Voltage

A test piece was dipped in an insulating oil bath, and an alternating voltage was applied between the copper foil and the aluminum plate at room temperature. The voltage at which dielectric breakdown occurred was measured.

### T-Peel Strength Test

The copper foil of the laminated board was etched with a 10 mm-wide pattern to produce a sample. Then, the substrate and the copper foil were peeled at a rate of 50 mm/minute while keeping the copper foil perpendicular with respect to the substrate, and the T-peel strength (N/cm) at the peeling was measured.

As a result of the evaluations in accordance with the aforementioned evaluation methods, the thermal conductivity was 10.8 W/mK, the T-peel strength was 20.5 N/cm, the withstanding voltage was 4.5 kV, and the solder resistance was acceptable at 300° C. for 4 minutes.

### Comparative Example 1

100 parts of a bisphenol A epoxy resin (Trade name: “EP 4100G”, epoxy equivalent 190, manufactured by Adeka Corporation), 85 parts of an acid anhydride curing agent (Trade name: “EH 3326”, acid value 650, manufactured by Adeka Corporation), and 100 parts of toluene as the solvent were employed instead of the liquid crystal polyester solution A. In the same manner as in Example 1, blending with 65% by volume filling ratio of alumina, stirring, applying on a copper foil, and drying were performed. The resultant product as it is was laminated on aluminum without performing a heat treatment. The laminated product was thermally adhered by heating at 180° C. and 50 kg/cm² for 1.5 hours for thermal adhesion.

The obtained metal base circuit board had a thermal conductivity of 3.4 W/mK, which was a much lower value than that of the examples that used a liquid crystal polyester.

### Example 2

70% by volume filling ratio of boron nitride (Trade name: “HP-40”, average particle size 5 to 8 μm manufactured by Mizushima Ferrroalloy Co., Ltd.) was blended with 100 parts of liquid crystal polyester solution A. Then, a metal base circuit board was produced in the same manner as in Example 1.

The obtained metal base circuit board had a high thermal conductivity of 16.8 W/mK, as well as a T-peel strength of 7.6 N/cm, a withstanding voltage of 4.5 kV, and an acceptable solder resistance at 300° C. of 4 minutes.

### Comparative Example 2

70% by volume filling ratio of boron nitride was blended with 100 parts of the epoxy resin and the acid anhydride curing agent used in Comparative Example 1. Then, a metal base circuit board was produced in the same procedures as in Comparative Example 1.

The obtained metal base circuit board had a thermal conductivity of 5.2 W/mK, which was a significantly lower value than that of the examples that used a liquid crystal polyester as a host material.

### INDUSTRIAL APPLICABILITY

Thus, since the metal base circuit board according to the present invention is configured such that the resin component constituting a host material for the insulating layer itself has a high thermal conductivity, even if the amount of the inorganic filler is reduced, the thermal conductivity of the insulating layer can be maintained at a high level. Consequently, the thermal conductivity of the insulating layer can be improved while simultaneously ensuring the insulation properties and mechanical strength of the insulating layer. Therefore, the metal base circuit board according to the present invention has high heat dissipation properties as well as excellent mechanical strength, so that a product obtained using the metal base circuit board can be subject to cutting and pressing. Further, the product can be obtained at a low cost, and can be applied in a wide range of fields including fields in which ceramic base circuit boards have mainly been used.

1. A metal base circuit board comprising a metal substrate, an insulating layer provided on the metal substrate, and a conductive foil for circuit formation that is provided on the insulating layer, wherein:
the metal substrate has a thermal conductivity of 60 W/mK or more and a thickness of 0.2 to 5.0 mm, and
the insulating layer is formed using an insulating material composition in which an inorganic filler having a thermal conductivity of 30 W/mK or more is dispersed in a non-anisotropic liquid crystal polyester solution.

2. The metal base circuit board according to claim 1, wherein an insulating material constituting the insulating layer has a thermal conductivity of 6 to 30 W/mK.

3. A method for producing the metal base circuit board of claim 1, comprising:
an applied insulating-material-composition layer formation step of applying an insulating material composition containing a non-anisotropic liquid crystal polyester solution and an inorganic filler having a thermal conductivity of 30 W/mK or more on a surface of a metal substrate having a thermal conductivity of 60 W/mK or more and a thickness of 0.2 to 5.0 mm to form an applied insulating-material-composition layer;
an insulating material layer formation step of drying the applied insulating-material-composition layer to form an insulating material layer;
an insulating layer formation step of heat-treating the insulating material layer to obtain an insulating layer;
a lamination step of bringing the conductive foil into contact with an exposed surface of the insulating layer formed on the surface of the metal substrate to form a multi-layer structure in which the insulating layer is provided between the metal substrate and the conductive foil; and
after the lamination step, a thermal adhesion step of heating the insulating layer to adhere the insulating layer with the metal substrate and the conductive foil.

4. A method for producing the metal base circuit board of claim 1, comprising:
an applied insulating-material-composition layer formation step of applying an insulating material composition containing a non-anisotropic liquid crystal polyester solution and an inorganic filler having a thermal conductivity of 30 W/mK or more on a surface of a conductive foil to form an applied insulating-material-composition layer;
an insulating material layer formation step of drying the applied insulating-material-composition layer to form an insulating material layer;
an insulating layer formation step of heat-treating the insulating material layer to obtain an insulating layer;
a lamination step of bringing an exposed surface of the insulating layer formed on the surface of the conductive foil into contact with a surface of the metal substrate to form a multi-layer structure in which the insulating layer is provided between the metal substrate and the conductive foil; and
after the lamination step, a thermal adhesion step of heating the insulating layer to adhere the insulating layer with the metal substrate and the conductive foil.
